(19) United States
(12) Patent Application Publication
(10) Pub. No.: US 2026/0206618 A1
(43) Pub. Date: Jul. 16, 2026

(54) INTEGRATED PACKING SUBSTRATE WITH INTERPOSER FUNCTION AND MANUFACTURING METHOD FOR THE SAME

(71) Applicant: THINKTRANS SEMICONDUCTOR TECHNOLOGY LTD., Wuhan, Hubei (CN)

(72) Inventor: Yong ZHAO, Wuhan, Hubei (CN)

(73) Assignee: ShTHINKTRANS SEMICONDUCTOR TECHNOLOGY LTD., Wuhan, Hubei (CN)

(21) Appl. No.: 19/136,295

(22) PCT Filed: Dec. 6, 2023
(86) PCT No.: PCT/CN2023/136679

§ 371 Date: Jun. 6, 2025

(30) Foreign Application Priority Data
Dec. 6, 2022 (CN) 202211554746.8

(51) Int. Cl. H10W 70/60; H10W 70/05; H10W 70/652; H10W 70/695; H10W 90/10

(52) U.S. Cl. CPC H10W 70/614; H10W 70/05; H10W 70/652; H10W 70/695; H10W 90/10

(57) ABSTRACT

An integrated packaging substrate with an interposer function and its manufacturing method are provided. Specifically, an integrated packaging substrate with an interposer function includes a packaging substrate containing substrate circuitry and an interposer layer integrally integrated on the packaging substrate. Correspondingly, fine circuitry is provided on and/or within the interposer layer. As needed, the fine circuitry of the interposer layer forms an electrical connection with the substrate circuitry of the packaging substrate to enable electrical connectivity between the packaging substrate and a bare chip attached to the interposer layer. Accordingly, the interposer layer functions to directly interconnect the bare chip with the integrated packaging substrate of the present invention, thereby achieving the conventional interposer function. Additionally, a manufacturing method for the integrated packaging substrate with an interposer function is disclosed.

### TECHNICAL FIELD

The present invention relates to a field of integrated circuit (IC) packaging substrates. Specifically, the present invention relates to an integrated packaging substrate that utilizes photosensitive or non-photosensitive insulating materials as a dielectric layer and metal materials such as copper as conductive lines, thereby producing a packaging substrate with multiple layers of finer circuitry and interposer functionality. Additionally, the present invention relates to a method for manufacturing such an integrated packaging substrate.

### DESCRIPTION OF RELATED ART

Currently, conventional packaging substrates (or carrier boards) contain circuitry with precision ranging from a few micrometers to tens of micrometers, while chips, such as bare dies (or dies), contain nanoscale circuitry. Consequently, an interposer is typically required to achieve electrical connectivity between the packaging substrate and the die, facilitating the connection between circuitry with significantly different precision scales.

An interposer, such as a silicon interposer, serves as an intermediary layer for die-to-die and die-to-substrate interconnections, playing a critical role in connecting the circuitry of the die to the circuitry of the packaging substrate. As illustrated in FIG. 1, this necessitates the interposer having fine circuitry and through-silicon vias (TSVs) for connection to the substrate. However, the TSV process is costly, and the silicon wafer (or glass) base material of the interposer also contributes to its high cost. Moreover, due to the use of semiconductor wafer fabrication equipment, the size of silicon interposers is limited, preventing the production of larger dimensions. These issues hinder the broader application of interposers.

To address the technical limitations and high costs of silicon interposers, Intel developed the Embedded Multi-Die Interconnect Bridge (EMIB) technology. This technology employs a smaller silicon bridge, embedded within the substrate as shown in FIG. 2, to implement the finer linewidth portion of die-to-die bridging. In comparison to silicon interposers, EMIB technology offers reductions in size and cost, along with improved yield. However, this technology introduces additional processes for embedding the EMIB silicon bridge into the substrate and still relies on semiconductor wafer fabrication for the silicon bridge, leaving room for improvement in cost and yield.

### SUMMARY OF INVENTION

To better address the issues associated with silicon interposers and silicon bridges, enhance design flexibility for die-to-substrate and die-to-die interconnections, and advance the wiring precision of packaging substrates to meet future demands for finer circuitry, the present invention provides an integrated packaging substrate with an interposer function. This substrate eliminates the need for a separate interposer or silicon bridge, enabling direct connection with one or more dies while achieving submicron linewidth and spacing. Specifically, the present invention enables traditional substrate materials, such as BF (e.g., ABF, NBF), BT, and FR4, to perform the functions of a silicon interposer or silicon bridge without requiring silicon wafers (or glass).

In one embodiment, an insulating material paste, such as polyimide (PI) paste, or an insulating material film, such as a PI film, is coated or laminated onto conventional substrate materials (e.g., BF, BT, FR4), and photolithography or etching is used to fabricate a substrate with inter-chip and chip-to-substrate signal interconnection capabilities. This substrate achieves ultrafine linewidths, even at submicron levels, meeting the high-precision demands of ICs, reducing the need for numerous interconnection lines and solder balls, and employing well-established manufacturing processes to meet demands such as short signal transmission distances in chipsets, rapid signal transmission among multiple chips, rapid signal transmission between the substrate and individual chips, and low cost.

In one aspect, the present invention provides a manufacturing method for an integrated packaging substrate. First, a substrate comprising one or more layers of materials such as BT, BF, or FR4 is provided, with substrate circuitry formed in each layer. Then, on the substrate with the substrate circuitry, a PI paste is coated or a PI film is laminated to form one or more PI film layers, thereby creating an interposer layer that enables chip-to-substrate or inter-chip interconnections. The interposer layer, together with the integrally formed packaging substrate, constitutes the integrated packaging substrate of the present invention. Optionally, the interposer layer may be located in the uppermost layers, lowermost layers, intermediate layers of the substrate, or any combination thereof. Within the interposer layer, circuitry having linewidths of, for example, hundreds of nanometers or more, along with interconnection vias, is formed. Given the extreme fineness of the circuitry, a full-additive or semi-additive process is employed. The seed layer used for the additive or semi-additive process may be formed by electroless copper plating, sputtering, or ion implantation coating. Finally, after forming the required circuitry layers and vias, the integrated packaging substrate of the present invention can be solder-ball bonded to a chip, such as a die. Without altering the production process of the existing substrate, the present invention enhances wiring capability, provides interposer functionality, offers a simpler, more reliable, and mature manufacturing method compared to conventional interposer fabrication techniques, while also eliminating the need for costly silicon wafers.

In another aspect, the present invention provides a processing method and structure for an integrated packaging substrate. Specifically, the processing method avoids the use of conventional silicon substrates, reduces the number of solder ball bonding steps by at least one, and shortens signal transmission paths, thereby better meeting or exceeding the signal speed and signal loss requirements of modern chipsets. Furthermore, by incorporating slots and/or openings in the interposer layer, the present invention integrates redistribution layer (RDL) processes with high-precision exposure and etching techniques, enabling the fabrication of substrates with extremely fine circuitry. This approach allows the direct formation of an interposer functional layer using RDL processes on standard substrates, advancing the achievable linewidth in the packaging substrate industry to the scale of hundreds of nanometers. As a result, the invention supports the industry's trend toward finer line widths and overcomes the existing limitation of several-micron-level circuitry in conventional packaging substrates. Compared to existing silicon-based interposer processes, the present invention is also more cost-effective.

According to the present invention, an integrated packaging substrate with an interposer function is provided, including: a packaging substrate including substrate circuitry; and an interposer layer integrally integrated on the packaging substrate, the interposer layer being provided with fine circuitry thereon and/or therein; wherein the fine circuitry of the interposer layer is electrically connected to the substrate circuitry of the packaging substrate to enable electrical connectivity between the packaging substrate and a chip element mounted on the interposer layer. In one embodiment, the interposer layer includes a photosensitive PI film or photosensitive PI paste. In one embodiment, the interposer layer comprises a non-photosensitive polyimide (PI) film or non-photosensitive PI paste. In one embodiment, the packaging substrate includes one or more materials selected from BF, BT, and FR4. In one embodiment, the interposer layer includes slots and/or openings for forming connection circuitry.

According to the present invention, a manufacturing method for an integrated packaging substrate with an interposer function is provided, the manufacturing method including following steps:
providing a packaging substrate comprising substrate circuitry;
providing a photosensitive polyimide (PI) film layer on a surface of the packaging substrate;
forming vias and line gaps in the photosensitive PI film layer by exposure and development;
forming a conductive seed layer on a surface of the photosensitive PI film layer, inside the vias, and inside the line gaps, thereby obtaining a prefabricated packaging substrate;
applying a dry film or photoresist on the surface of the prefabricated packaging substrate to form a circuitry pattern in which regions requiring via filling and circuitry routing are exposed;
electroplating the prefabricated packaging substrate such that an electroplated layer covers the regions requiring via filling and circuitry routing; and
removing the dry film or the photoresist from the prefabricated packaging substrate and performing flash etching to remove exposed portions of the conductive seed layer, forming circuitry in the photosensitive PI film layer, thereby achieving interconnection between circuitry in the photosensitive PI film layer and the substrate circuitry of the packaging substrate.

In one embodiment, the steps from the step of providing the photosensitive PI film layer to the step of removing the dry film or the photoresist and performing flash etching are repeated one or more times to provide one or more photosensitive PI film layers, thereby forming the interposer layer of the integrated packaging substrate. In one embodiment, the interposer layer forms an interposer functional layer comprising one or more layers of fine circuitry. In one embodiment, a thickness of the conductive seed layer is in a range from 80 nm to 2000 nm.

According to the present invention, a manufacturing method for an integrated packaging substrate with an interposer function is provided, the manufacturing method including following steps:
providing a packaging substrate comprising substrate circuitry;
providing a non-photosensitive polyimide (PI) film layer on a surface of the packaging substrate;
applying a first dry film or first photoresist on the non-photosensitive PI film layer, followed by exposure and development to form vias and line gaps;
etching to remove portions of the non-photosensitive PI film layer not protected by the first dry film or the photoresist;
performing a film removal process to remove the first dry film or the photoresist from the non-photosensitive PI film layer;
forming a conductive seed layer on a surface of the non-photosensitive PI film layer, inside the vias, and inside the line gaps, thereby obtaining a prefabricated packaging substrate;
applying a second dry film or second photoresist on a surface of the prefabricated packaging substrate, followed by exposure and development to form a pattern in which regions requiring via filling and circuitry routing are exposed;
electroplating the prefabricated packaging substrate such that an electroplated layer covers the regions requiring via filling and circuitry routing; and
removing the second dry film or the second photoresist from the prefabricated packaging substrate and performing flash etching to remove exposed portions of the conductive seed layer, forming circuitry in the non-photosensitive PI film layer, thereby achieving interconnection between circuitry in the non-photosensitive PI film layer and the substrate circuitry of the packaging substrate.

In one embodiment, wherein the steps from the step of providing the non-photosensitive PI film layer to the step of removing the second dry film or the second photoresist and performing flash etching are repeated one or more times to provide one or more non-photosensitive PI film layers, thereby forming the interposer layer of the integrated packaging substrate. In one embodiment, the interposer layer forms an interposer functional layer comprising one or more layers of fine circuitry. In one embodiment, a thickness of the conductive seed layer is in a range from 80 nm to 2000 nm.

Variations and improvements to the above technical solutions fall within the scope and spirit of the present invention and may be further described herein.

### BRIEF DESCRIPTION OF DRAWINGS

The present invention is described in detail below with reference to the accompanying drawings and specific embodiments. The advantages and implementations of the present invention will be more evident from this description. The content depicted in the drawings serves solely to illustrate the invention and should not be interpreted as imposing any limitations. The drawings are schematic representations and not drawn strictly to scale. In the drawings:

FIG. 1 is a schematic cross-sectional view illustrating a related-art configuration where a silicon interposer is used to interconnect a die and a packaging substrate.

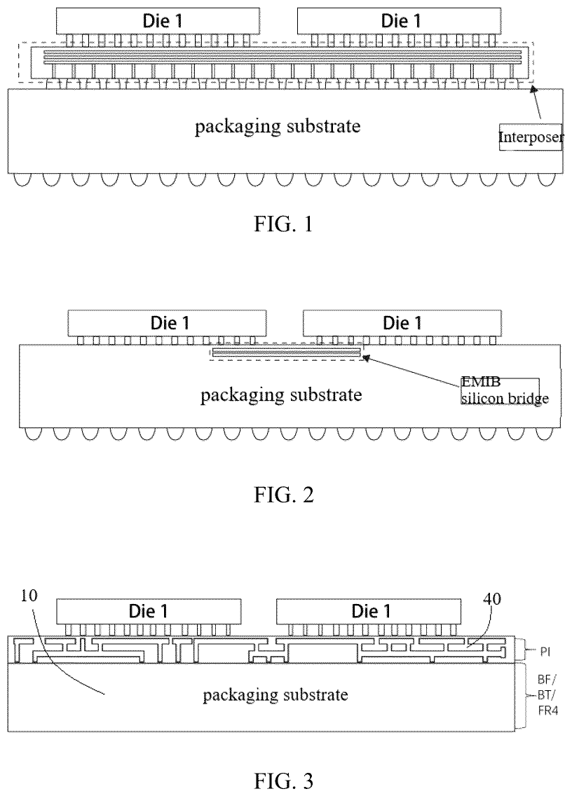

FIG. 2 is a schematic cross-sectional view illustrating a related-art configuration where an EMIB is used to interconnect a die and a packaging substrate.

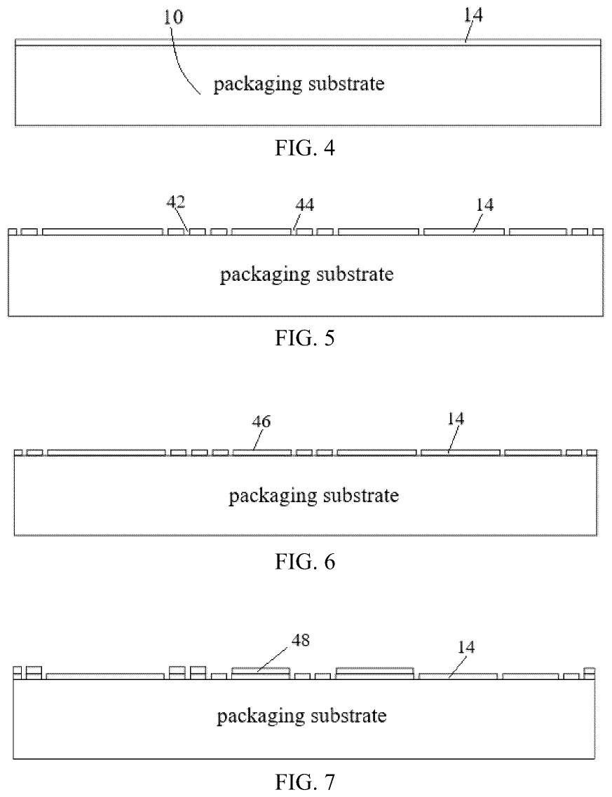

FIG. 3 is a schematic cross-sectional view of an integrated packaging substrate with an interposer function according to one embodiment of the present invention.

FIGS. 4 to 10 are schematic cross-sectional views illustrating the steps of a manufacturing method for an integrated packaging substrate according to a first embodiment of the present invention.

FIGS. 11 to 19 are schematic cross-sectional views illustrating the steps of the manufacturing method for the integrated packaging substrate according to a second embodiment of the present invention.

FIG. 20 is a process flow diagram of the manufacturing method for the integrated packaging substrate according to a first exemplary embodiment of the present invention.

FIG. 21 is a process flow diagram of the manufacturing method for the integrated packaging substrate according to a second exemplary embodiment of the present invention.

### DETAILED DESCRIPTION OF EMBODIMENTS OF THE INVENTION

Embodiments of the present invention are described in detail below with reference to the accompanying drawings, wherein one or more examples are illustrated. Each example is provided to explain the invention and is not intended to limit it. Indeed, it will be apparent to those skilled in the art that various modifications and variations can be made to the present invention without departing from its scope or spirit. For instance, features illustrated or described as part of one embodiment may be used in conjunction with another embodiment to yield yet another embodiment. Thus, it is intended that the present invention encompasses such modifications and variations that fall within the scope of the appended claims and their equivalents.

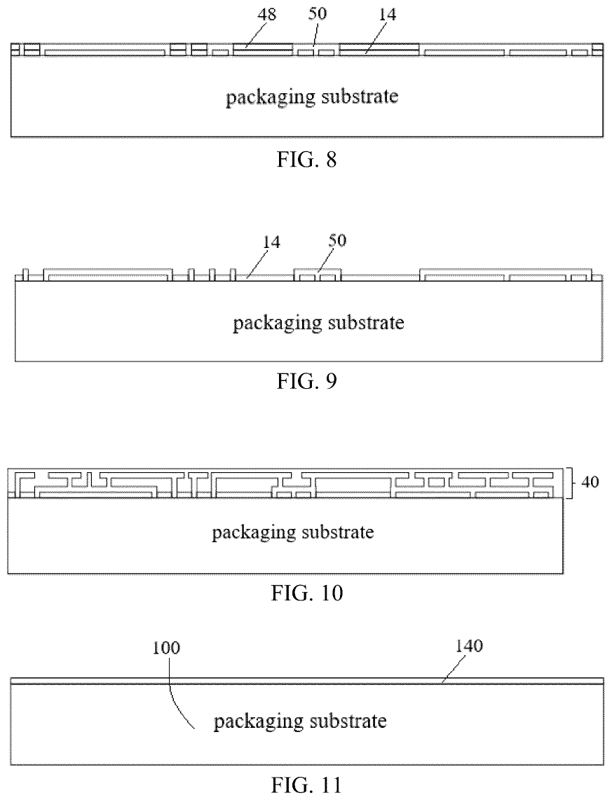

FIG. 3 illustrates a schematic cross-sectional view of an integrated packaging substrate with an interposer function according to one embodiment of the present invention. The integrated packaging substrate primarily comprises a packaging substrate 10 and an interposer layer 40 integrally integrated thereon. In one embodiment, a packaging substrate 10 is a laminate comprising one or more layers. In each layer of the substrate 10, processes such as hole drilling, electroless copper plating, copper electroplating, and etching are selectively performed to form single-sided or double-sided substrate circuitry. As needed, electrical interconnections between the substrate circuitry of various layers of the substrate 10 may be formed. Correspondingly, the interposer layer 40 also comprises one or more layers, with fine circuitry provided in each layer of the interposer layer 40. As needed, the fine circuitry in the interposer layer 40 forms an electrical connection with the substrate circuitry of the packaging substrate 10 to enable electrical connectivity between the packaging substrate 10 and bare chips, such as a first die (Die 1) and a second die (Die 2), attached to the interposer layer 40. Thus, the interposer layer 40 acts as an intermediary layer between the dies (Die 1, Die 2) and the packaging substrate 10, facilitating their interconnection and achieving the conventional interposer function. In one embodiment, the interposer layer 40 includes an insulating material base. Preferably, a polyimide (PI) film layer is used as the insulating material base to form the interposer layer. Compared to other insulating materials, PI materials exhibit certain flowability and surface planarization properties, enabling finer circuitry fabrication.

Additionally, in one embodiment, Die 1 and Die 2 are connected to the integrated packaging substrate, particularly to the interposer layer 40, via solder ball bonding. In an example, a solder ball windowing process may utilize the PI film opening technique described in this disclosure. Optionally, conventional green oil windowing (solder mask opening) may also be used for solder ball bonding. Alternatively, Die 1 and Die 2 can also be connected to the interposer layer 40 through a conductive film with Au balls, for example, materials with anisotropic conductive film (ACF) properties. This connection method is commonly used for interconnecting ICs in display modules or flexible printed circuits (FPCs) with other electronic components.

As shown in the drawing, the depiction of two interconnected dies is for illustrative purposes only. In practice, the present invention may involve a single die connected to the substrate or multiple dies interconnected. Optionally, multiple dies of different types and sizes may be interconnected. Optionally, both sides of the substrate may be connected to dies. Furthermore, in the drawing, the pins of the dies and the circuitry of the substrate with interposer functionality are schematic, and they may vary in density and size. Although FIG. 3 shows two similar dies, in practice, the dies may encompass various possibilities. For example, the dies may include, but are not limited to, any of CPUs, GPUs, ASICs, or other chips with computational functions. When other interconnection needs arise, alternative chipsets or circuit boards may be used instead of dies.

Compared to conventional substrate production processes, the integrated packaging substrate of the present invention eliminates the need for a separate interposer or silicon bridge, enabling direct connection with dies while achieving submicron linewidth and spacing. Thus, the integrated packaging substrate not only enhances wiring capability but also provides interposer functionality, avoiding the need for costly silicon wafers.

Next, several embodiments of a manufacturing method for an integrated packaging substrate according to the present invention are described.

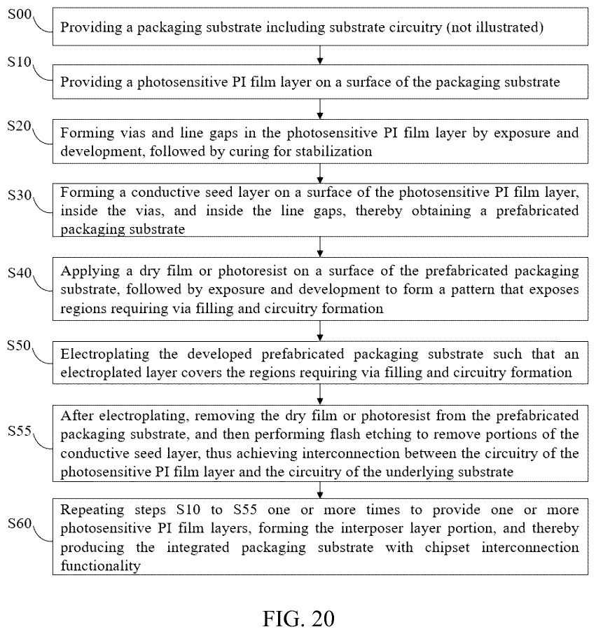

FIG. 20 is a process flow diagram of the manufacturing method for the integrated packaging substrate according to a first exemplary embodiment of the present invention. The manufacturing method for the integrated packaging substrate generally includes the following steps:
Step S00: Providing a packaging substrate 10 including substrate circuitry (not illustrated);
Step S10: Providing a photosensitive PI film layer 14 on a surface of the packaging substrate 10;
Step S20: Forming vias 42 and line gaps 44 in the photosensitive PI film layer 14 by exposure and development, followed by curing for stabilization;
Step S30: Forming a conductive seed layer 46 on a surface of the photosensitive PI film layer 14, inside the vias 42, and inside the line gaps 44, thereby obtaining a prefabricated packaging substrate;
Step S40: Applying a dry film or photoresist 48 on a surface of the prefabricated packaging substrate, followed by exposure and development to form a pattern that exposes regions requiring via filling and circuitry formation;
Step S50: Electroplating the developed prefabricated packaging substrate such that an electroplated layer 50 covers the regions requiring via filling and circuitry formation;
Step S55: After electroplating, removing the dry film or photoresist 48 from the prefabricated packaging substrate, and then performing flash etching to remove portions of the conductive seed layer 46, thus achieving interconnection between the circuitry of the photosensitive PI film layer 14 and the circuitry of the underlying substrate; and
Step S60: Repeating steps S10 to S55 one or more times to provide one or more photosensitive PI film layers 14, forming the interposer layer 40, and thereby producing the integrated packaging substrate with chipset interconnection functionality.

Optionally, after step S60, additional layers may be added to the interposer layer 40 of the resulting integrated packaging substrate to provide one or more additional substrate circuitry layers.

In step S00, a packaging substrate 10 containing substrate circuitry (not shown) is provided. The packaging substrate 10 is a laminate comprising one or more layers. In each layer of the substrate 10, single-sided or double-sided substrate circuitry is selectively printed. As needed, electrical interconnections between the substrate circuitry of the various layers of the substrate 10 may be formed. The packaging substrate 10 and the substrate circuitry prepared thereon are manufactured using conventional substrate production processes. For brevity, these processes are not described in detail.

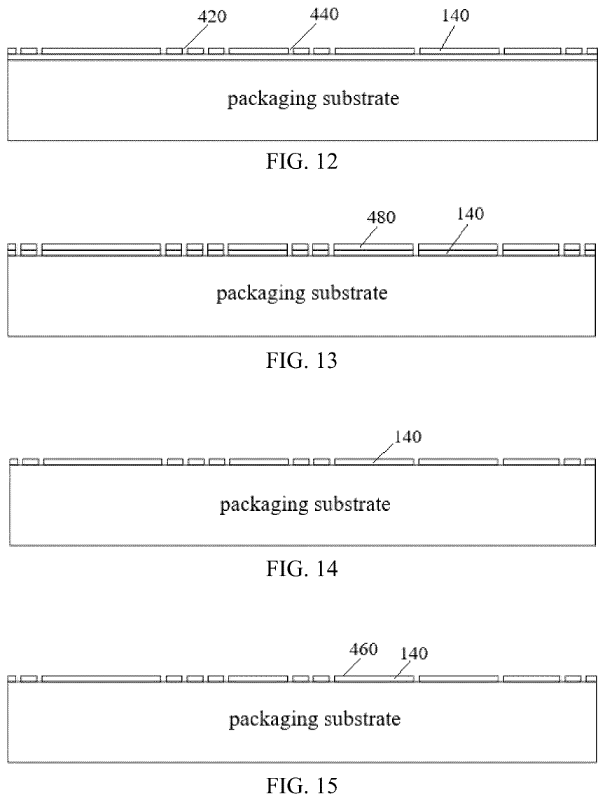

In step S10, a photosensitive PI film layer 14 is provided on a surface of the packaging substrate 10. For example, this surface typically refers to the surface of the packaging substrate 10 intended for chip bonding, such as the upper surface, lower surface, or both. FIG. 4 illustrates a schematic cross-sectional view of a conventional process-completed packaging substrate coated with the photosensitive PI film layer 14 according to one embodiment of the present invention. Herein, the photosensitive PI film layer refers to a photosensitive insulating material base forming the interposer layer 40, including but not limited to photosensitive PI film layers, such as PIC films or PSPI pastes. In one embodiment, providing the photosensitive PI film layer 14 may involve hot-pressing (e.g., vacuum hot-pressing) a photosensitive PI film onto the surface of the packaging substrate 10. The photosensitive PI film is a dry film material with hot-pressing compatibility, such as a PIC film. In one embodiment, the photosensitive PI film adheres to the surface of the substrate after exposure, development, and thermal drying. However, if the resolution properties of the photosensitive PI film cannot meet the exposure resolution requirements, the manufacturing method for the integrated packaging substrate described below in the second exemplary embodiment of the present invention may be used to achieve the desired resolution circuitry. Alternatively, providing the photosensitive PI film layer 14 may involve directly coating a photosensitive PI paste onto the surface of the packaging substrate 10. The photosensitive PI paste, such as PSPI paste, has coatable and dryable properties. In one embodiment, the photosensitive PI paste adheres to the surface of the substrate after exposure, development, and thermal drying. However, if the resolution properties of the photosensitive PI paste cannot meet the exposure resolution requirements, the manufacturing method for the integrated packaging substrate described below in the second exemplary embodiment may be used to achieve the desired resolution circuitry. In an example, a thermal baking process may be employed as needed to facilitate the formation of the photosensitive PI film layer 14.

In step S20, the photosensitive PI film layer 14 is by exposure and development to form vias 42 and line gaps 44, followed by curing for stabilization. FIG. 5 illustrates a schematic cross-sectional view of the photosensitive PI film layer 14 on the packaging substrate 10 after exposure, development, and curing according to one embodiment of the present invention. For example, the photosensitive PI film layer 14 is exposed directly using a film, mask, or laser direct imaging (LDI). After exposure, the photosensitive PI film layer 14 is developed to form the vias 42 with a diameter of 1 μm or greater and the line gaps 44 with dimensions of hundreds of nanometers or greater. In one embodiment, the photosensitive PI film layer is further cured at high temperature for stabilize its form. For instance, in one embodiment, the photosensitive PI film layer 14 is baked and cured, causing a polymerization reaction in the photosensitive PI material to ensure stable properties.

In step S30, a conductive seed layer 46 is formed on the surface of the photosensitive PI film layer 14, inside the vias 42, and inside the line gaps 44, thereby producing a prefabricated packaging substrate. FIG. 6 illustrates a schematic cross-sectional view of the conductive seed layer 46 being formed on the packaging substrate 10 according to one embodiment of the present invention. For example, the conductive seed layer 46 is formed on the surface of the photosensitive PI film layer 14, inside the vias 42, and inside the line gaps 44 through electroless copper plating, thus resulting in the prefabricated packaging substrate. In another embodiment, the conductive seed layer 46 is formed on the photosensitive PI film layer 14, inside the vias 42, and inside the line gaps 44 through sputtering. In yet another embodiment, the conductive seed layer 46 is formed on the photosensitive PI film layer 14, inside the vias 42, and inside the line gaps 44 through ion implantation coating. Preferably, the thickness of the conductive seed layer ranges from 80 nm to 2000 nm. In one embodiment of this invention, ion implantation coating is used if mass production is hindered by inadequate bonding strength due to surface roughness or material characteristics.

In step S40, a dry film or photoresist 48 is applied on the surface of the prefabricated packaging substrate, followed by exposure and development to form a pattern, where regions requiring via filling and circuitry formation are exposed. FIG. 7 illustrates a schematic cross-sectional view of the prefabricated packaging substrate with the dry film or photoresist 48 applied, exposed, and developed according to one embodiment of the present invention. For example, a dry film is attached to the surface of the prefabricated packaging substrate to form a circuitry pattern via exposure and development. Alternatively, the circuitry pattern may be formed by coating a liquid photoresist onto the surface of the prefabricated packaging substrate. The resulting circuitry pattern exposes the regions requiring via filling and circuitry formation for subsequent electroplating.

In step S50, the developed prefabricated packaging substrate is electroplated such that an electroplated layer 50 covers the regions requiring via filling and circuitry formation. Preferably, the prefabricated packaging substrate undergoes pretreatment before electroplating. Pretreatment methods may include surface cleaning, such as wiping the substrate surface with alcohol-soaked gauze to remove contaminants or immersing the substrate in a cleaning solution with ultrasonic cleaning. FIG. 8 illustrates a schematic cross-sectional view of the electroplated layer 50 being formed on the prefabricated packaging substrate according to one embodiment of the present invention. For example, the prefabricated packaging substrate with the exposed circuitry pattern is electroplated, such as with copper, to cover the exposed pattern portions with the electroplated layer 50, increasing its thickness to the desired level. In one embodiment of the present invention, if the copper thickness uniformity after electroplating does not meet product requirements, polishing may be employed to achieve the desired uniformity. Optionally, this polishing step may be performed after electroplating and before the film removal step described below.

In step S55, the dry film or photoresist 48 is removed from the prefabricated packaging substrate after electroplating, followed by flash etching to remove portions of the conductive seed layer 46, achieving interconnection between the circuitry of the photosensitive PI film layer 14 and the circuitry of the underlying substrate. FIG. 9 illustrates a schematic cross-sectional view of the prefabricated packaging substrate after film removal and flash etching according to one embodiment of the present invention. For example, an alkaline solution or an organic film removal liquid is used to remove the dry film or photoresist 48 from the electroplated prefabricated packaging substrate. Further, flash etching is performed to etch away the portions of the conductive seed layer 46 that are not thickened by electroplating, thereby forming the desired pattern and achieving the interconnection between the desired circuitry pattern and the vias below.

In step S60, steps S10 to S55 are repeated one or more times to provide one or more photosensitive PI film layers 14, which results in the formation of the interposer layer 40, and consequently, the production of the integrated packaging substrate with chipset interconnection functionality. FIG. 10 illustrates a schematic cross-sectional view of the integrated packaging substrate according to one embodiment of the present invention. As shown in the drawing, the integrated packaging substrate includes the packaging substrate 10 and the interposer layer 40 integrally integrated thereon. For example, the interposer layer 40 includes two layers of fine circuitry to achieve the interposer function. Of course, as needed, the interposer layer 40 may include one or more layers of fine circuitry to achieve the interposer function. Further, as shown in FIG. 3, the interposer layer 40 serves as an intermediary layer between the die and the packaging substrate, facilitating their interconnection and achieving the functions of conventional interposers.

It should be noted that the thickness of the conductive seed layer is closely related to pretreatment before electroplating, the electroplating process, and flash etching. In one embodiment, the thickness of the conductive seed layer in the present invention ranges from 80 nm to 2000 nm. If the conductive seed layer is too thin, it may be etched away during pretreatment or electroplating, failing to conduct electricity during the electroplating process; if the conductive seed layer is too thick, excessive flash etching becomes necessary, which risks preventing the desired linewidth and spacing from being achieved. Considering the strong correlation between the conductive seed layer thickness and the three processes of pretreatment, electroplating, and flash etching, the thickness of the conductive seed layer is defined within the range of 80 nm to 2000 nm. Preferably, the thickness of the conductive seed layer according to the present invention is 800 nm. The metal used to form the conductive seed layer can be one or more of Cu, Ta, TaN/Ta alloy, TiN, TiW, Cr, Ti, Mo, MoTi alloy, Ni, NiCu, or combinations thereof. In one embodiment, electroless copper plating is used to form the conductive seed layer, using, for example, metal Cu to create a single-layer conductive seed layer. In another embodiment, sputtering or other dry coating methods are used to form the conductive seed layer, allowing selection of metals other than Cu as a base layer paired with Cu to form a two-layer conductive seed layer structure. In one embodiment of the present invention, a two-layer structure consisting of a Ni base layer and a Cu top layer is used to form the conductive seed layer, with a total thickness of 800 nm. Considering the cost of sputtering, a thinner Ni/Cu layer may be deposited to a thickness of 150 nm and then thickened to 800 nm via electroplating. This thickness can be adjusted based on production capacity, cost, and process window.

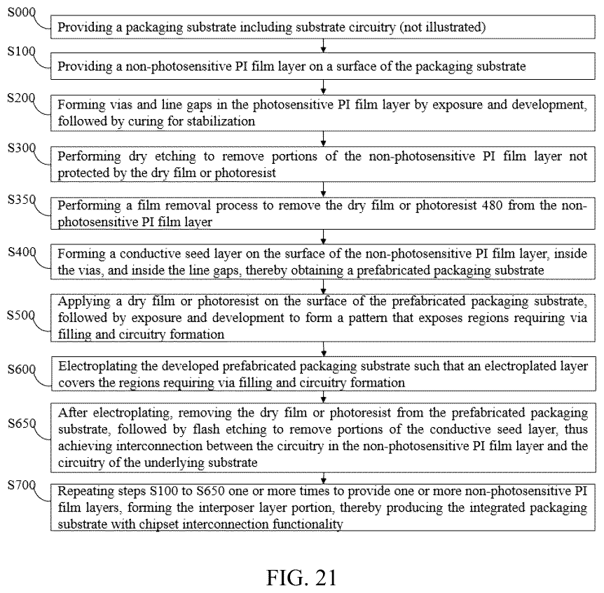

FIG. 21 is a process flow diagram of a manufacturing method for an integrated packaging substrate according to a second exemplary embodiment of the present invention. The manufacturing method generally includes the following steps:
Step S000: Providing a packaging substrate 100 including substrate circuitry (not illustrated);
Step S100: Providing a non-photosensitive PI film layer 140 on a surface of the packaging substrate 100;
Step S200: Applying a dry film or photoresist 480 on the non-photosensitive PI film layer 140, followed by exposure and development to form vias 420 and line gaps 440;
Step S300: Performing dry etching to remove portions of the non-photosensitive PI film layer 140 not protected by the dry film or photoresist 480;
Step S350: Performing a film removal process to remove the dry film or photoresist 480 from the non-photosensitive PI film layer 140;
Step S400: Forming a conductive seed layer 460 on the surface of the non-photosensitive PI film layer 140, inside the vias 420, and inside the line gaps 440, thereby obtaining a prefabricated packaging substrate;
Step S500: Applying a dry film or photoresist 580 on the surface of the prefabricated packaging substrate, followed by exposure and development to form a pattern that exposes regions requiring via filling and circuitry formation;
Step S600: Electroplating the developed prefabricated packaging substrate such that an electroplated layer 500 covers the regions requiring via filling and circuitry formation;
Step S650: After electroplating, removing the dry film or photoresist 580 from the prefabricated packaging substrate, followed by flash etching to remove portions of the conductive seed layer 460, thus achieving interconnection between the circuitry in the non-photosensitive PI film layer 140 and the circuitry of the underlying substrate; and
Step S700: Repeating steps S100 to S650 one or more times to provide one or more non-photosensitive PI film layers 140, forming the interposer layer 400, thereby producing the integrated packaging substrate with chipset interconnection functionality.

Optionally, after step S700, additional layers may be added to the interposer layer 400 of the resulting integrated packaging substrate to provide one or more additional substrate circuitry layers.

In step S000, a packaging substrate 100 including substrate circuitry (not shown) is provided. Herein, the packaging substrate 100 is similar to the packaging substrate 10 described above. For brevity, it is not described in detail.

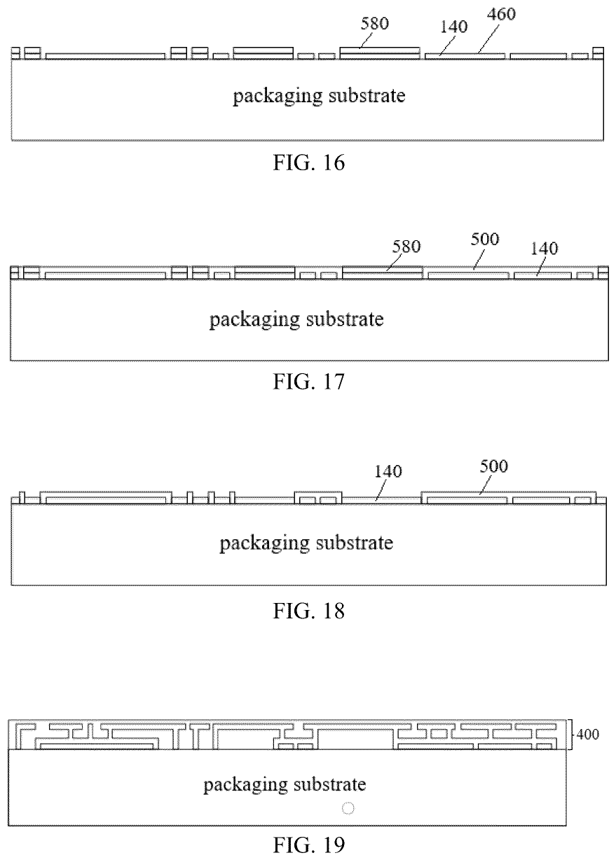

In step S100, a non-photosensitive PI film layer 140 is provided on a surface of the packaging substrate 100. For example, this surface typically refers to the surface of the packaging substrate 100 intended for chip bonding, such as the upper surface, lower surface, or both. FIG. 11 illustrates a schematic cross-sectional view of a conventional process-completed packaging substrate coated with the non-photosensitive PI film layer 140 according to one embodiment of the present invention. In one embodiment, providing the non-photosensitive PI film layer 140 may involve hot-pressing (e.g., vacuum hot-pressing) a non-photosensitive PI film onto the surface of the packaging substrate 100. The non-photosensitive PI film is a dry film material with hot-pressing compatibility, such as a laminable non-photosensitive PI material. In one embodiment, the non-photosensitive PI film adheres to the substrate surface after thermal drying. Alternatively, providing the non-photosensitive PI film layer 140 may involve coating a non-photosensitive coating film onto the surface of the packaging substrate 100. The non-photosensitive coating film, such as a non-photosensitive PI paste, has coatable and dryable properties. In one embodiment, the non-photosensitive PI paste adheres to the substrate surface after thermal drying. In the present invention, the PI film layers 14 and 140 are not limited to the PI dry films and PI pastes mentioned herein; photosensitive or non-photosensitive acrylic pastes and dry films, widely used as planarization layers in display panels, or other coatable and curable organic materials may also be employed.

In step S200, a dry film or photoresist 480 is applied on the non-photosensitive PI film layer 140, followed by exposure and development to form vias 420 and line gaps 440. FIG. 12 illustrates a schematic cross-sectional view of the non-photosensitive PI film layer 140 on the packaging substrate 100 after exposure and development according to one embodiment of the present invention. For example, photoresist is coated onto or a dry film is directly attached onto the non-photosensitive PI film layer 140, followed by exposure. After exposure, the photoresist or dry film is developed to form vias 420 with a diameter of 1 μm or greater and line gaps 440 with dimensions of hundreds of nanometers or greater.

In step S300, dry etching is performed to remove portions of the non-photosensitive PI film layer 140 not protected by the dry film or photoresist 480. In one embodiment, an etching gas for dry etching may include carbon tetrafluoride (CF₄) and oxygen (O₂). FIG. 13 illustrates a schematic cross-sectional view of the non-photosensitive PI film layer 140 on the packaging substrate 100 after dry etching according to one embodiment of the present invention. As shown in the drawing, portions of the non-photosensitive PI film layer 140 not protected by the dry film or photoresist have been etched away, exposing parts of the surface of the packaging substrate 100. In other words, the vias 420 and the line gaps 440 are deepened by etching to reach the surface of the packaging substrate 100. In the present invention, PI etching is not limited to dry etching. Alternatively, wet etching can be employed to remove the non-photosensitive PI film layer 140, provided that the required precision is maintained.

In step S350, a film removal process is performed to remove the dry film or photoresist 480 from the non-photosensitive PI film layer 140. In one embodiment, NaOH or an organic film removal liquid is selected based on the type of dry film or photoresist for the removal operation. FIG. 14 illustrates a schematic cross-sectional view of the non-photosensitive PI film layer 140 covered with the dry film or photoresist 480 after film removal according to one embodiment of the present invention. As shown in the drawing, the dry film or photoresist covering the non-photosensitive PI film layer 140 has been removed. Similar to FIG. 5, the vias 420 with a diameter of 1 μm or greater and the line gaps 440 with dimensions of hundreds of nanometers or greater are formed in the non-photosensitive PI film layer 140.

In step S400, a conductive seed layer 460 is formed on the surface of the non-photosensitive PI film layer 140, inside the vias 420, and inside the line gaps 440, thereby producing a prefabricated packaging substrate. FIG. 15 illustrates a schematic cross-sectional view of the conductive seed layer 460 being formed in the non-photosensitive PI film layer 140 on the packaging substrate 100 according to one embodiment of the present invention. For example, the conductive seed layer 460 is formed on the surface of the non-photosensitive PI film layer 140, inside the vias 420, and inside the line gaps 440 through electroless copper plating, thus obtaining the prefabricated packaging substrate. In another embodiment, the conductive seed layer 460 is formed on the non-photosensitive PI film layer 140, inside the vias 420, and inside the line gaps 440 through sputtering. In yet another embodiment, the conductive seed layer 460 is formed on the non-photosensitive PI film layer 140, inside the vias 420, and inside the line gaps 440 via ion implantation coating. Preferably, the conductive seed layer has a thickness in the range of 80 nm to 2000 nm.

In step S500, a dry film or photoresist 580 is applied on the surface of the prefabricated packaging substrate, followed by exposure and development to form a pattern, where regions requiring via filling and circuitry formation are exposed. FIG. 16 illustrates a schematic cross-sectional view of the prefabricated packaging substrate with the dry film or photoresist 480 applied, exposed, and developed according to one embodiment of the present invention. For example, a dry film is attached to the surface of the prefabricated packaging substrate to form a circuitry pattern via exposure and development. Alternatively, the circuitry pattern can be formed by coating a liquid photoresist onto the surface of the prefabricated packaging substrate. The resulting circuitry pattern exposes the regions requiring via filling and circuitry formation for subsequent electroplating.

In step S600, the developed prefabricated packaging substrate is electroplated such that an electroplated layer 500 covers the regions requiring via filling and circuitry formation. In one embodiment of the present invention, the prefabricated packaging substrate undergoes pretreatment before electroplating. Pretreatment methods may include surface cleaning, such as wiping the substrate surface with alcohol-soaked gauze to remove contaminants or immersing the substrate in a cleaning solution with ultrasonic cleaning. FIG. 17 illustrates a schematic cross-sectional view of the electroplated layer 500 being formed on the prefabricated packaging substrate according to one embodiment of the present invention. For example, the prefabricated packaging substrate with the exposed circuitry pattern is electroplated, such as with copper, such that the electroplated layer 500 covers the exposed circuitry pattern and increases in thickness to a desired level. In one embodiment of the present invention, if the copper thickness uniformity after electroplating does not meet product requirements, polishing can be employed to achieve the desired uniformity. Optionally, this polishing process or step may be performed after electroplating and before the film removal step described below.

In step S650, the dry film or photoresist 580 is removed from the prefabricated packaging substrate after electroplating, followed by flash etching to remove portions of the conductive seed layer 460, achieving interconnection between the circuitry in the non-photosensitive PI film layer 140 and the circuitry of the underlying substrate. FIG. 18 illustrates a schematic cross-sectional view of the prefabricated packaging substrate after film removal and flash etching according to one embodiment of the present invention. For example, an alkaline solution or an organic film removal liquid is used to remove the dry film or photoresist 580 from the electroplated prefabricated packaging substrate. Further, flash etching is performed to etch away the portions of the conductive seed layer 460 that were not thickened by electroplating, thereby forming the desired pattern and achieving the interconnection between the desired circuitry pattern and the vias below.

In step S700, steps S100 to S650 are repeated one or more times to provide one or more non-photosensitive PI film layers 140, thereby forming the interposer layer 400 and producing the integrated packaging substrate with chipset interconnection functionality. FIG. 19 illustrates a schematic cross-sectional view of the integrated packaging substrate according to one embodiment of the present invention. As shown in the drawing, the integrated packaging substrate includes the packaging substrate 100 and the interposer layer portion 400 integrally integrated thereon. For example, the interposer layer 400 includes two layers of fine circuitry to achieve the interposer function. Of course, as needed, the interposer layer 400 may include one or more layers of fine circuitry to achieve the interposer function. Further, as shown in FIG. 3, the interposer layer 40 serves as an intermediary layer between the die and the packaging substrate, facilitating their interconnection and achieving the functions of a conventional interposer.

It should be noted that the substrate layers with chipset interconnection functionality mentioned in the present invention are not limited to the final layers of the substrate; they may also be located in the initial layers, intermediate layers, or any layer of the substrate as needed. In the present invention, the description is provided based on the layers where conventional interposer functionality is typically located.

Compared to conventional methods that only allow circuitry to be arranged on a PI film or other dielectric surfaces, the present invention also enables circuitry to be embedded within the PI film through the use of PI film openings. This offers the advantage of reducing product thickness compared to conventional processes. Moreover, since the present invention employs PI materials with certain flowability and surface planarization properties, it facilitates the formation of finer circuitry.

In addition to integrating the interposer with the substrate, the integrated packaging substrate of the present invention also reduces the number of solder ball bonding processes. Furthermore, the integrated packaging substrate not only reduces signal loss and reflection during signal transmission, but also mitigates the potential impact of alpha radiation from solder balls on high-frequency signals, thereby providing significant benefits for high-frequency signal transmission.

This written description provides examples, including the best mode, to disclose the invention and enable those skilled in the art to practice the invention, including making and using any devices or systems and performing any incorporated methods. The patentable scope of the invention is defined by the claims and may include other examples conceived by those skilled in the art. If such other examples have structural elements that do not differ from the literal language of the claims, or if they include equivalent structural elements with insubstantial differences from the literal language of the claims, they are considered to fall within the scope of the claims.

1. An integrated packaging substrate with an interposer function, comprising:
a packaging substrate, the packaging substrate including substrate circuitry; and
an interposer layer integrally integrated on the packaging substrate, the interposer layer being provided with fine circuitry thereon and/or therein;
wherein the fine circuitry of the interposer layer is electrically connected to the substrate circuitry of the packaging substrate to provide electrical connectivity between the packaging substrate and a chip element mounted on the interposer layer.

2. The integrated packaging substrate according to claim 1, wherein the interposer layer comprises a photosensitive polyimide (PI) film or a photosensitive PI paste.

3. The integrated packaging substrate according to claim 1, wherein the interposer layer comprises a non-photosensitive polyimide (PI) film or a non-photosensitive PI paste.

4. The integrated packaging substrate according to claim 1, wherein the packaging substrate comprises at least one dielectric layer formed of a material selected from the group consisting of photosensitive polyimide (PI), non-photosensitive polyimide (non-PI), Ajinomoto Build-up Film (ABF), a material having properties substantially identical to ABF, bismaleimide triazine (BT) resin, a material having properties substantially identical to BT resin, and polybenzoxazole (PBO).

5. The integrated packaging substrate according to claim 1, wherein the interposer layer comprises slots and/or openings for forming connection circuitry.

6. A manufacturing method for an integrated packaging substrate with an interposer function, the manufacturing method comprising following steps:
providing a packaging substrate comprising substrate circuitry;
providing a photosensitive polyimide (PI) film layer on a surface of the packaging substrate;
forming vias and line gaps in the photosensitive PI film layer by exposure and development;
forming a conductive seed layer on a surface of the photosensitive PI film layer, inside the vias, and inside the line gaps, thereby obtaining a prefabricated packaging substrate;
applying a dry film or photoresist on the surface of the prefabricated packaging substrate to form a circuitry pattern in which regions requiring via filling and circuitry routing are exposed;
electroplating the prefabricated packaging substrate such that an electroplated layer covers the regions requiring via filling and circuitry routing; and
removing the dry film or the photoresist from the prefabricated packaging substrate and performing flash etching to remove exposed portions of the conductive seed layer, forming circuitry in the photosensitive PI film layer, thereby achieving interconnection between circuitry in the photosensitive PI film layer and the substrate circuitry of the packaging substrate.

7. The manufacturing method according to claim 6, wherein the steps from the step of providing the photosensitive PI film layer to the step of removing the dry film or the photoresist and performing flash etching are repeated one or more times to provide one or more photosensitive PI film layers, thereby forming the interposer layer of the integrated packaging substrate.

8. The manufacturing method according to claim 7, wherein the interposer layer forms an interposer functional layer comprising one or more layers of fine circuitry.

9. The manufacturing method according to claim 6, wherein a thickness of the conductive seed layer is in a range from 80 nm to 2000 nm.

10. A manufacturing method for an integrated packaging substrate with an interposer function, the manufacturing method comprising following steps:
providing a packaging substrate comprising substrate circuitry;
providing a non-photosensitive polyimide (PI) film layer on a surface of the packaging substrate;
applying a first dry film or first photoresist on the non-photosensitive PI film layer, followed by exposure and development to form vias and line gaps;
photolithographic etching to remove portions of the non-photosensitive PI film layer unprotected by the first dry film or the photoresist;
performing a film removal process to remove the first dry film or the photoresist from the non-photosensitive PI film layer;
forming a conductive seed layer on a surface of the non-photosensitive PI film layer, inside the vias, and inside the line gaps, thereby obtaining a prefabricated packaging substrate;
applying a second dry film or second photoresist on a surface of the prefabricated packaging substrate, followed by exposure and development to form a pattern in which regions requiring via filling and circuitry routing are exposed;
electroplating the prefabricated packaging substrate such that an electroplated layer covers the regions requiring via filling and circuitry routing; and
removing the second dry film or the second photoresist from the prefabricated packaging substrate and performing flash etching to remove exposed portions of the conductive seed layer, forming circuitry in the non-photosensitive PI film layer, thereby achieving interconnection between circuitry in the non-photosensitive PI film layer and the substrate circuitry of the packaging substrate.

11. The manufacturing method according to claim 10, wherein the steps from the step of providing the non-photosensitive PI film layer to the step of removing the second dry film or the second photoresist and performing flash etching are repeated one or more times to provide one or more non-photosensitive PI film layers, thereby forming an interposer layer of the integrated packaging substrate.

12. The manufacturing method according to claim 11, wherein the interposer layer forms an interposer functional layer comprising one or more layers of fine circuitry.

13. The manufacturing method according to claim 10, wherein a thickness of the conductive seed layer is in a range from 80 nm to 2000 nm.
